(19) United States
(12) Patent Application Publication
(10) Pub. No.: US 2007/0204898 A1
(43) Pub. Date: Sep. 6, 2007

(54) Thermoelectric device

(76) Inventors: Mark Logan, Pleasant Valley, NY (US); Frederick A. Flitsch, New Windsor, NY (US); Lloyd Wright, Hopewell Junction, NY (US); Lloyd Young, Pleasant Valley, NY (US)

Correspondence Address: Joseph P. Kincart, Esq., 8153 Middle Fork Way, Jacksonville, FL, 32256, US

(21) Appl. No.: 11/526,418

(22) Filed: Sep. 25, 2006

Related U.S. Application Data
(60) Provisional application No. 60/719,824, filed on Sep. 23, 2005.

(51) Int. Cl. H01L 35/02; H01L 35/34

(52) U.S. Cl. 136/230; 136/201

(57) ABSTRACT

A thermoelectric device and a method for manufacturing a thermoelectric device is presented that provides greater efficiency of operation and highly accurate temperature control. According to the present invention, a thermal gap is created between N-type material and P-type materials on a monolayer basis to create a highly efficient thermoelectric device. In some embodiments, two or more gold sphere monolayers are spincast on a conductive platform with insulator layers also laid down. Endpoints can also be etched into the gold spheres.

### CROSS REFERENCE TO RELATED APPLICATIONS

This application claims priority to Provisional Application No. 60/719,824 filed Sep. 23, 2005 and entitled: “Thermoelectric Device.” The contents of each are relied upon and incorporated herein by reference.

### FIELD OF THE INVENTION

This invention relates generally to devices with thermoelectric and thermodiodic characteristics. In particular the present invention relates to high efficiency thermoelectric devices and methods and systems for manufacturing the same.

### BACKGROUND

Thermocouples operating in accordance with the Peltier effect are well known in the arts. Applications for thermoelectric devices include heating, power generation and temperature sensing. However, the efficiency of previously known thermoelectric devices limited their usefulness.

As discovered by Peltier in 1835, arranging two dissimilar conductors next to each other and applying a voltage differential across the conductors can create a thermo electric device. More recently, thermoelectric devices have been formed with two dissimilar semiconductors, such as bismuth telluride (Bi₂Te₃) doped with selenium and antimony (Bi,Sb)₂Te₃ & Bi₂(Te,Se)₃ to form n-type and p-type materials. Other materials can include PbTe and SiGe. With a voltage applied across the two types of materials, the electrons in each material have a different potential energy. Therefore to move from one type of material to another type of material, the electrons must either absorb energy or release it, depending upon which direction they travel. The result is heat being absorbed on one side of the device and heat being released on the other.

The efficiency of a thermoelectric device is generally limited to its associated Carnot cycle efficiency reduced by a factor which is dependent upon the thermoelectric figure of merit of materials used in fabrication of the associated thermoelectric elements, ZT, where Z=α²/ρλ with α=the Seebeck coefficient (the change in voltage with temperature dV/dT), Σ=the electrical resistivity, and k =the thermal conductivity. As can be seen from the definition of Z, the efficiency of a thermoelectric device decreases with increasing thermal conductivity or electrical resistivity. Improving the efficiency of thermoelectric devices requires either increasing the Seebeck coefficient or reducing the thermal conductivity or electrical resistivity.

It is known in the art to manufacture a thermoelectric device by extruding a billet of P-type material to form a P-type extrusion, also extruding a billet of N-type material to form an N-type extrusion. The P and N-type extrusions are sliced into wafers, the wafers are sliced into small elements, and the elements are mechanically loaded into a matrix of a desired pattern and assembled upon an electrically insulating plate with small copper pads connecting all of the elements electrically in series and thermally in parallel on the plate.

The prior art also includes methods of forming a thermoelectric material by combining a P-type extrusion with a N-type extrusion to form a P/N-type billet. The P/N-type billet may be extruded to form a P/N-type extrusion having P-type regions, and N-type regions. According to this method, the number of P-type regions and N-type regions correspond with the number of P-type extrusions and N-type extrusions used to form the P/N-type billet.

In some prior art embodiments, a thermoelectric module includes two ceramic substrate plates that serve as a foundation and also as electrical insulation for P-type and N-type Bismuth Telluride blocks. A pattern of blocks is laid out on the ceramic substrates so that they are electrically connected in series configuration. The position of the blocks between the two ceramic substrates provides a parallel configuration for the thermal characteristics of the blocks. The ceramic plates also serve as insulation between a) the blocks internal electrical elements and a heat sink that will typically be placed in contact with the hot side and b) the blocks internal electrical elements and whatever may be in contact with the cold side surface.

Typical commercially available modules have an even number of P-type and N-type blocks. The blocks are arranged so that one of each type of block shares an electrical interconnection often referred to as a “couple.”

As discussed above, it is known for P-type to be fashioned from an alloy of Bismuth and the N-type to be fashioned from an alloy of Tellurium. Both Bismuth and Tellurium have different free electron densities at the same temperature. P-type blocks are composed of material having a deficiency of electrons while N-type has an excess of electrons. As current flows through the module (up and down through the blocks) the amperage attempts to establish equilibrium throughout the module. The current causes the P-type material to become analogous to a hot area that will be cooled and the N-type to become analogous to a cool area that will be heated. Since both materials are actually at the same temperature, the result of the applied current is that the hot side of the module is heated and the cold side of the module is cooled. Since direct current is applied, the direction of the current can be used to determine whether a particular side of the module will be cooled or heated. Simple reversal of the DC polarity will switch the hot and cold sides.

However, the efficiency of the prior art hinder many applications. Much materials research has been conducted in an effort to find bulk materials with a higher figure of merit than Bismuth-Telluride, to no avail. As a result, recent efforts have focused on optimizing the thermoelectric device construction, rather than the basic materials. Unfortunately, each of the published methods have significant limitations, for example:
1) Superlattice Structures: The method reduces thermal conductivity in thermoelectric devices via blocking phonon conduction by constructing electron energy level barriers and requires an array of hundreds of precisely deposited thin layers of BiTe doped at slightly different levels. The transistion in doping levels between layers must be very sharp, making fabrication of such devices very expensive and also very sensitive to diffusion of dopants, leading to reliability problems.
2) Thermionic Emission devices: These devices cool via emission of electrons at a relatively higher energy level from one surface to another surface at very close proximity whose electrons are at a slightly lower energy level. This method requires the two surfaces be maintained approximately 10 nm apart using piezoelectric devices. It also requires the use of exotic materials such as cesium. They are very expensive to manufacture and unreliable due to the difficulty in maintaining a uniform 10 nm gap within the device.
3) Lateral thin film devices: These devices have thin film channels of BiTe deposited laterally on the surface of wafers (increasing the thermal conduction path length) and then rely upon heat transfer pads to conduct heat vertically through the device to the object being cooled in an effort to focus the conduction of heat in high-conductivity channels while limiting the parasitic losses elsewhere. These devices still suffer from thermal conductivity both laterally between channels and vertically through the device.

### SUMMARY

Accordingly, the present invention provides devices with thermoelectric and thermodiodic characteristics and methods for manufacturing such devices. The present invention provides greater efficiency of operation and highly accurate temperature control. Advantages of the present invention include a highly efficient thermoelectric device that can also be used to transfer heat energy in one direction through the device and resist the heat energy passing back through the device.

In some embodiments a thermoelectric device may be formed by coating a conductor with metallurgy including one or more of: Au and Sn material and spin casting a first gold sphere monolayer onto the one or more of: Au and Sn material. A nanomaterial insulator material can be soaked over the first gold sphere monolayer and etched back to a depth exposing at least a portion of the first gold sphere monolayer. The first gold monolayer can also be etched back, for example, until endpoints are formed comprising the first gold sphere monolayer. A second gold monolayer can be spin cast on top of the nanomaterial insulator and an attaching layer of material can be applied to facilitate adhesion of the second gold monolayer and the first gold monolayer. In some embodiments, a metal film may be deposited over the attaching layer and a mask applied on top of the metal film.

Implementations of the present invention are wide ranging and can include, for example, improved methods and devices for cooling computer modules and other solid state technologies and reclamation of heat energy emanated from a combustion engine.

Other embodiments of the present invention can include a computerized system, executable software, or a data signal implementing the inventive methods of the present invention.

Various features and embodiments are further described in the following figures, drawings and claims.

Accordingly, the present invention provides a thermoelectric device and a method for manufacturing a thermoelectric device that provides greater efficiency of operation and highly accurate temperature control. According to the present invention, a thermal gap is created between N-type material and P-type materials on a monolayer basis to create a highly efficient thermoelectric device.

Other embodiments of the present invention can include a computerized system, executable software, or a data signal implementing the inventive methods of the present invention.

Various features and embodiments are further described in the following figures, drawings and claims.

### DESCRIPTION OF THE DRAWINGS

FIG. 1 illustrates a series of block diagrams implementing some embodiments of the present invention.

FIG. 2 through 17 illustrate additional block diagrams and method steps of manufacture implementing some embodiments of the present invention.

FIG. 18 illustrates some anomalies that may be encountered while practicing steps of the present invention.

FIG. 19 illustrates a device according to some embodiments of the present invention.

FIG. 20 illustrates a controller that may be used to implement some embodiments of the present invention.

### DETAILED DESCRIPTION

Overview

The present invention provides thermoelectric devices fashioned from layers of N-type and P-type materials and methods and systems to create the thermoelectric devices. According to the present invention, a Peltier effect is created by applying a current across a device with layers of dissimilar conductor material (or semiconductor material). In some embodiments, the layers across which the current is applied, can be as thin a monolayer. In addition, in some embodiments, an air gap across which a temperature differential is achieved can also be as thin as a monolayer.

Devices created according to the teaching of the present invention overcome limitations imposed upon the prior art which applied a current across blocks of dissimilar conductor material (or semiconductor material) to create a Peltier effect.

Methods

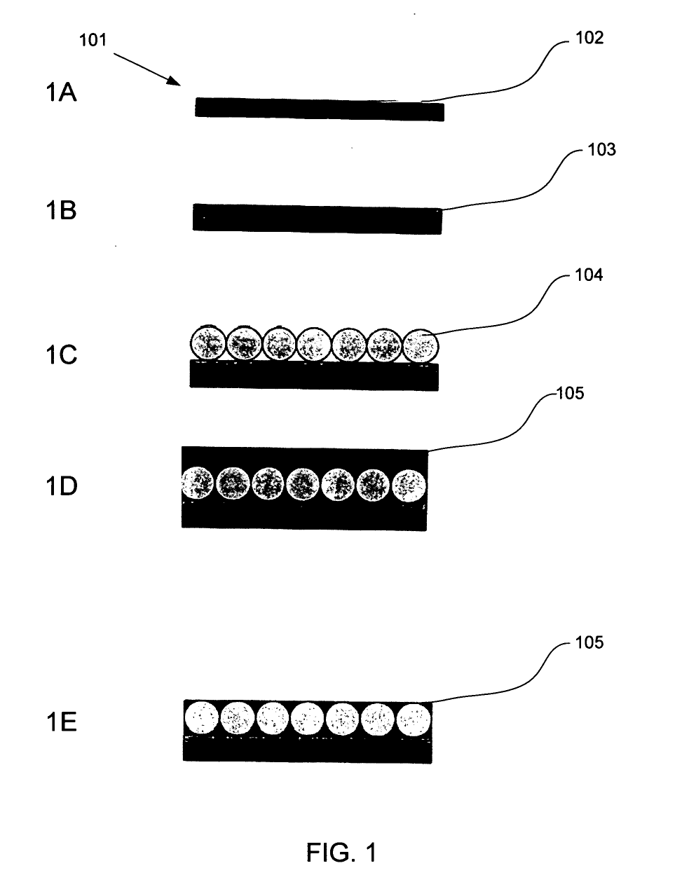

Referring now to FIG. 1 a basic process for creating a device according to some embodiments of the present invention, and suitable for generating a Peltier effect across layers N-type and P-type materials is illustrated. At 1A, according to the present invention, a flat conductor material 101, such as, for example, copper is provided with a first surface and a second surface and at least one of the first and second surfaces is a flat surface 102.

At 1B, the flat surface 102 is coated with a layer of solder material 103, such as, for example with Au/Sn solder material. The solder material 103 can be coated on to the flat surface via industry standard metallurgy processes.

At 1C, a monolayer 104, such as, for example, a gold sphere monolayer 104, is deposited on the Au/Sn solder material 103. The monolayer 104 can be deposited via spin casting, vapor deposition or other known process. In some preferred embodiments, the gold sphere monolayer 104 is deposited on a macroscopic level.

At ID, a nanomaterial insulator 105 is applied on and around the gold sphere monolayer 104. Preferably, the nanomaterial insulator 105 comprises a low conductivity material. At 1E the nanomaterial insulator 105 is etched back until endpoints from the gold sphere monolayer 104 are present through the nanomaterial insulator 105. The etch back process can include, for example, a wet etch or a dry etch. The wet etch may be more favorable, for example, if the nanomaterial is backside coated and the etch is performed in conjunction with a conductivity measurement.

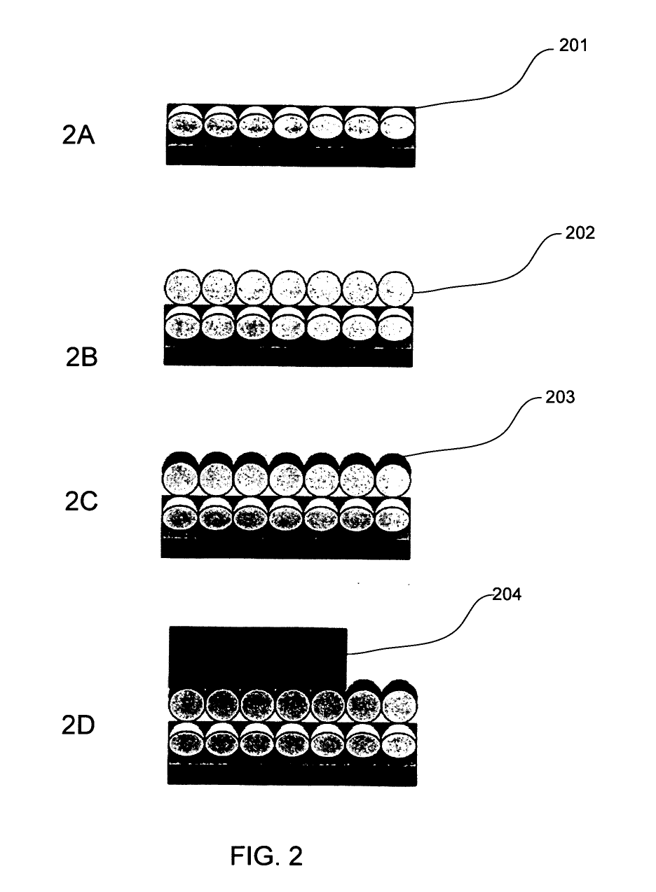

Referring now to FIG. 2, at 2A, in some embodiments, it is desirable to create more favorable emission fields, wherein the gold sphere monolayer 104 can be etched back to create air gaps 201 above the gold spheres and form points. Etching of the gold spheres can be accomplished with industry known practices.

At 2B, a second monolayer 202 is applied with known deposition methods, such as, for example, with spin casting or vapor deposition. At least a portion of the second monolayer 202 will align with openings in the first matrix, which creates two monolayers 104 and 202 separated by the air gap 201. The width of the air gap 201 can be controlled by the extent of the etching.

At 2C, the second monolayer 202 can be made to be more firmly attached to the first monolayer 104 by any known practice in the industry, such as, for example, through the application of a spin on glass layer 203 (hereinafter “SOG layer”). At 2D, a metal film 204 can be deposited over the SOG layer 203. The metal film can include for example, titanium or other conductive layer.

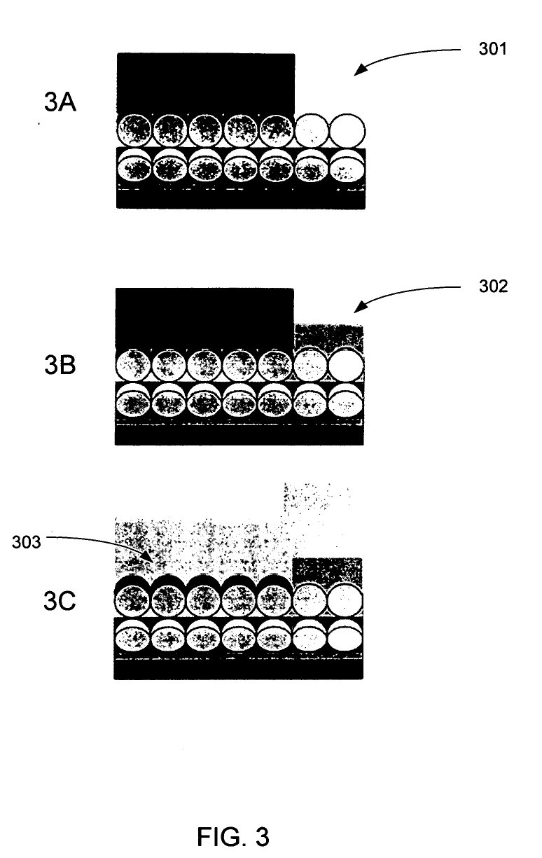

Referring now to FIG. 3, at 3A and 3B a mask 301-302 can be applied and the metal film 204 can be stripped according the mask 301-302. At 3C further processing can also include stripping and EVAP of the metal film 204 providing a pattern 303 of mask 301-302 and SOG 203.

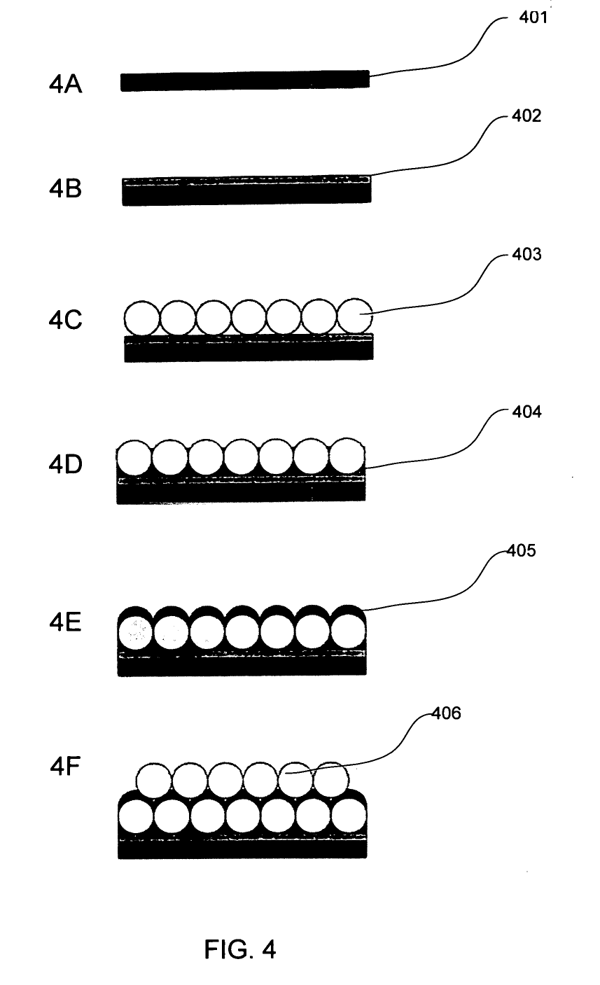

Referring now to FIG. 4, some additional embodiments of the present invention are illustrated. At 4A, a flat conductor 401, such as copper is formed as a thin or ultra thin platform.

At 4B, the flat conductor 401 is coated with a thin, high temperature solder, such as, for example, Au/Sn 402. At 4C, a gold sphere monolayer 403 is deposited, such as, for example, with spin casting. The monolayer can be applied in dimensions at the macroscopic level. At 4D, an insulator 404 of low conductivity material is soaked in, wherein, for example it will fill in between multiple interstitial spaces.

At 4E, an ALD insulator 405 is applied. In some embodiments, a layer of TiN film can be applied as an alternative to the ALD layer 405. The TiN film can be, for example, in the range of 50 Ang thick.

At 4F, a second monolayer 406 can be applied using, for example, a spin coating process.

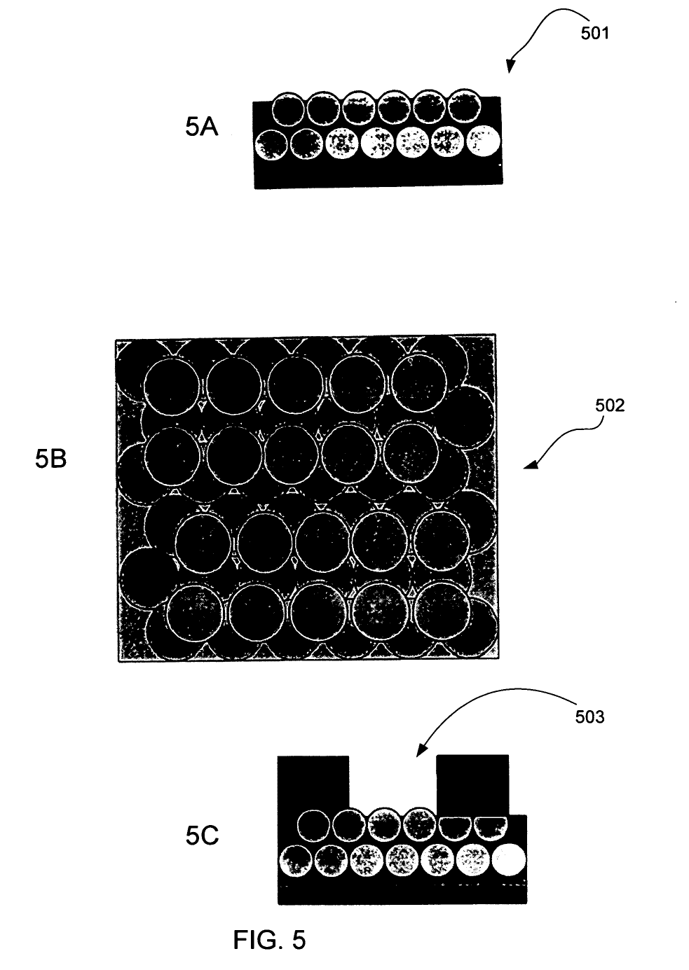

Referring now to FIG. 5, at 5A, S102 is deposited and etched 501 back to expose the gold endpoints. At 5B, a top view 502 of a thermoelectric device according to the present invention is shown following etch back to the gold endpoint. At 5C a side view 503 of the device with cutouts is also shown.

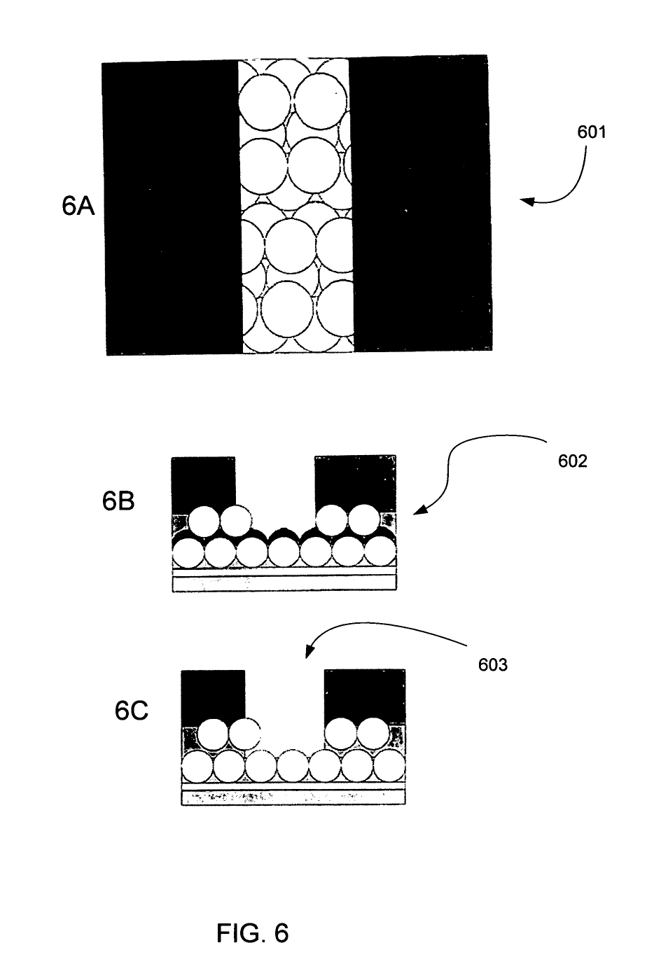

Referring now to FIG. 6, at 6A, a top view 601 illustrates the thermoelectric device with image cutouts and at 6B a side view 602 of the thermoelectric device with cutouts, including some sphere removal. At FIG. 6C, TiN (or ALD) barrier strip 603 is shown. In some embodiments, the chemistry needs to be inert to AU. In addition, some embodiments can target a strip of approximately one half of the distance between openings.

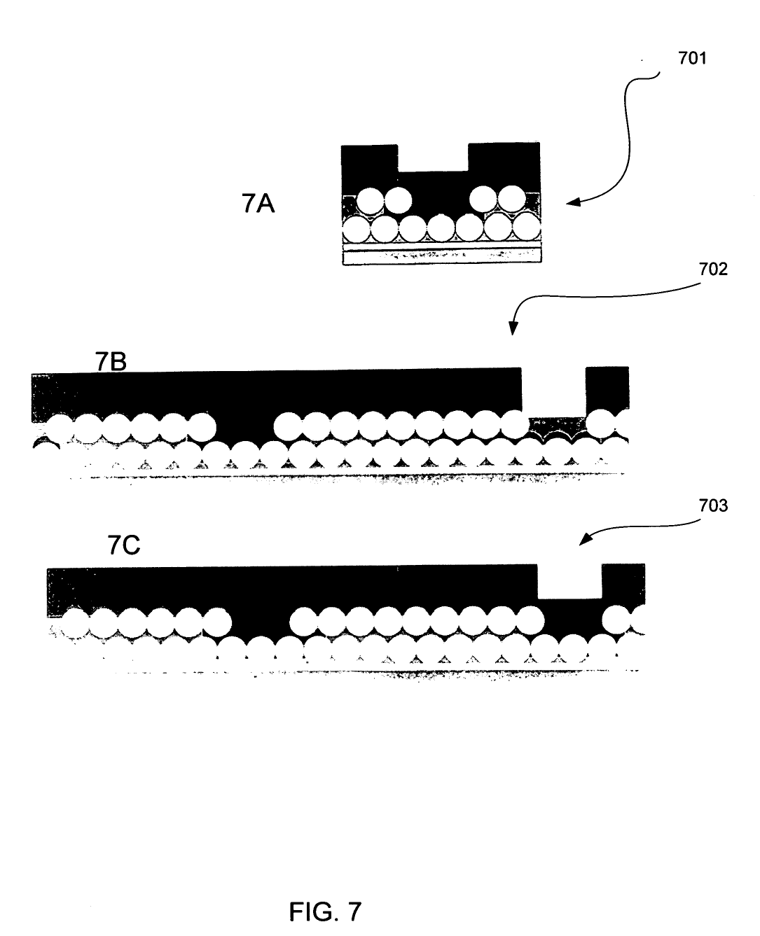

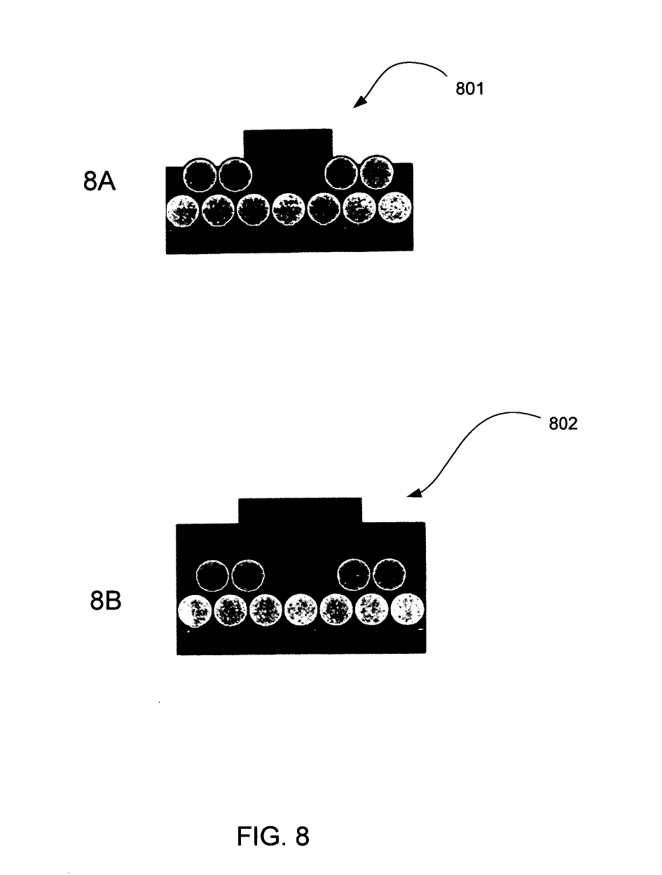

Referring now to FIGS. 7 and 8, at 7A, a light SOG 701 is shown after vacuum dry and inert backfill and at 7B & 7C, a repeat image 702-703 with ALD strip and SOG applied. At 8A, a side view 801 following strip resist and at 8B a side view 802 of a top contact following EVAP.

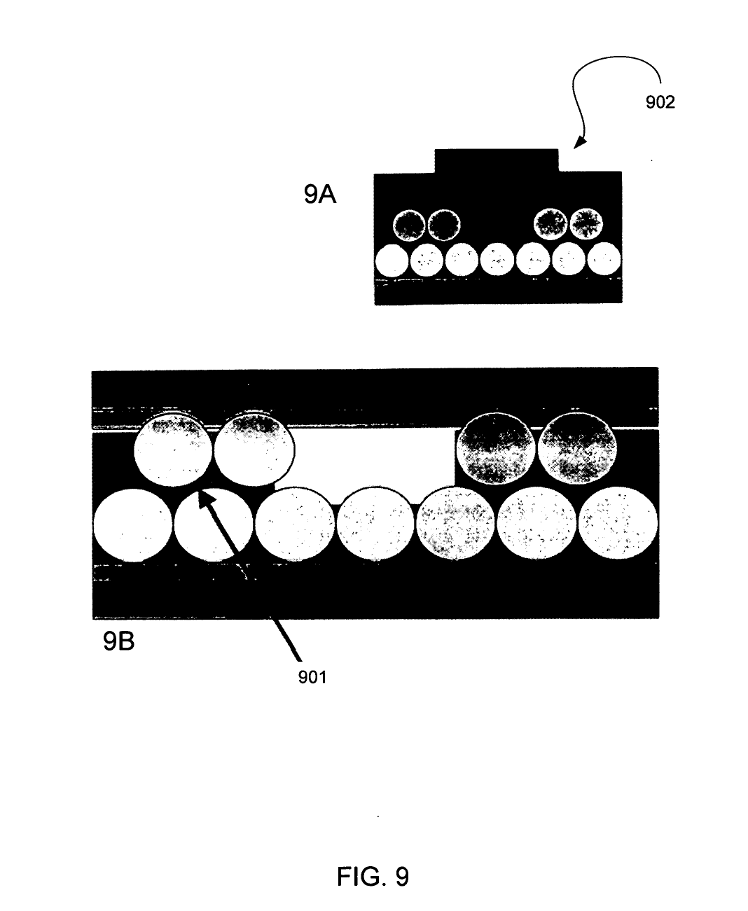

Referring now to FIG. 9, at 9A, a side view with sinter/anneal solder 902 shown and at 9B, a tunneling gap 901 is shown, where the ambient may be SOG chemical or near vacuum if TEOS is used for a black film dimension set by ALD film.

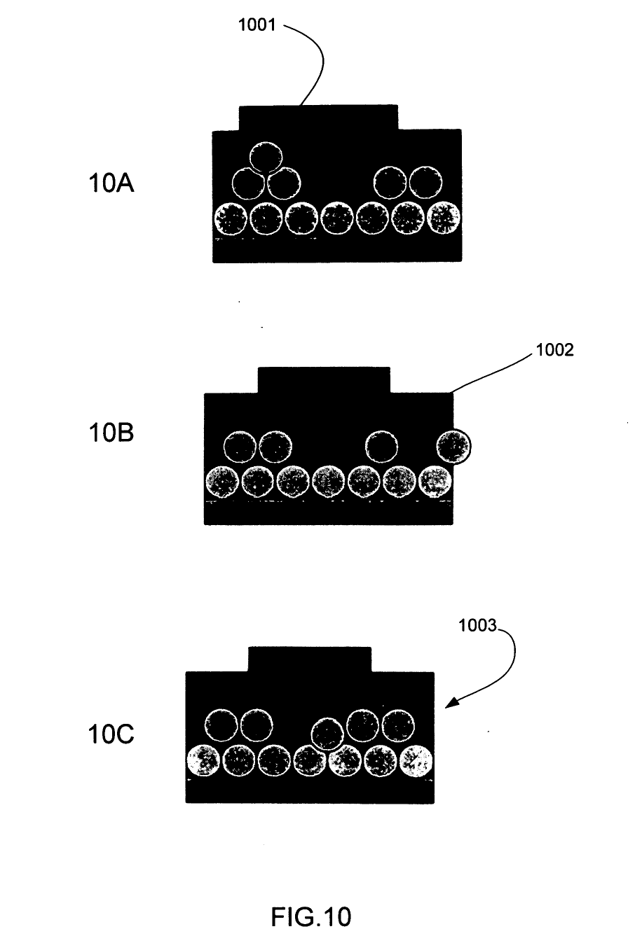

Referring now to FIG. 10, some anticipated anomalies are shown, each anomaly not greatly disrupting the process. At 10A, an extra atom 1001 is shown and at 10B a missing atom 1002 is shown. FIG. 10C illustrates an atom in the etch area.

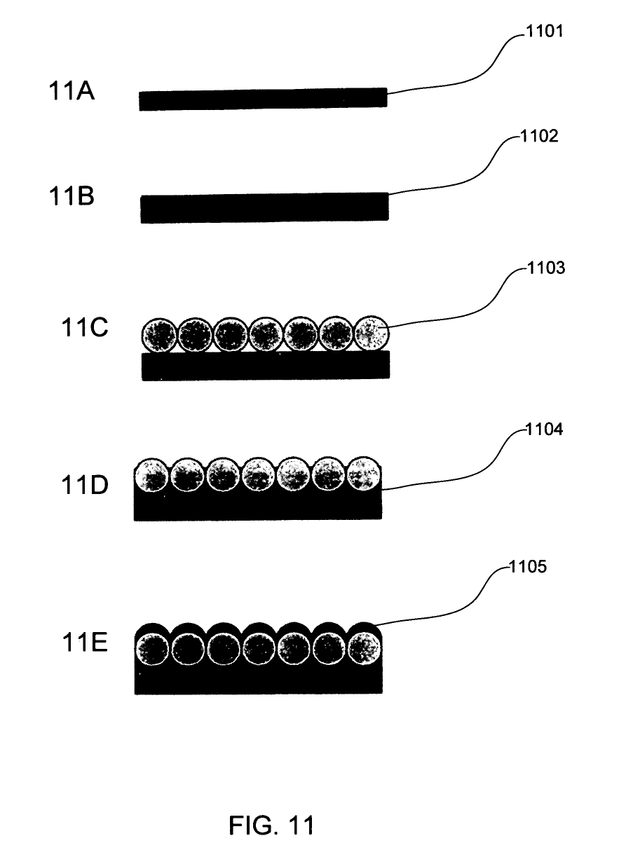

Referring now to FIG. 11, still other embodiments can include, at 11A, a flat conductor 1101, such as an ultra flat copper panel.

At 11B, the copper 1101 can be coated with a thin high temperature solder 1102 such as Au/Sn. At 11C, a gold sphere monolayer 1103 is spun on via spin casting or otherwise deposited, such as, for example through vapor deposition. In some preferred embodiments, the monolayer 1103 is applied at the macroscopic level.

At 11D, a low conductivity insulator 1104 is soaked in. In some preferred embodiments, the insulator 1104 also comprises a nanomaterial and at 11E, an ALD insulator or TiN film 1105 is applied. In some embodiments, the ALD insulator or TiN film 11 05 will be conformal to gold and will be applied to a thickness of about 50 Ang. In some embodiments, a cleaning process will be implemented prior to the application of the ALD insulator or TiN film which is conformal to gold.

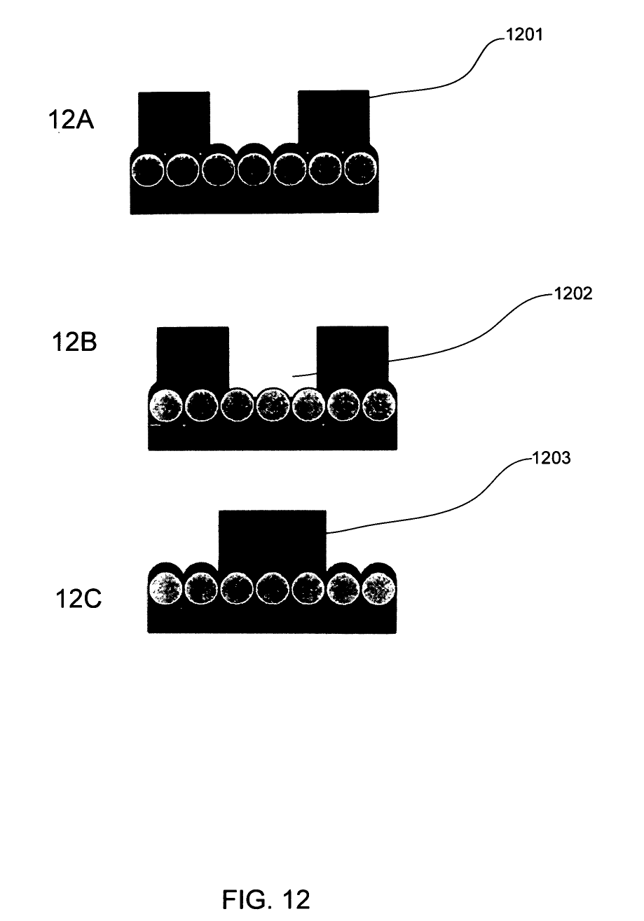

Referring now to FIG. 12, at 12A, a mask 1201 is applied and at 12B an ALD etch 1202 is performed for support pedestals. At 12C, a SOG then strip process is performed 1203.

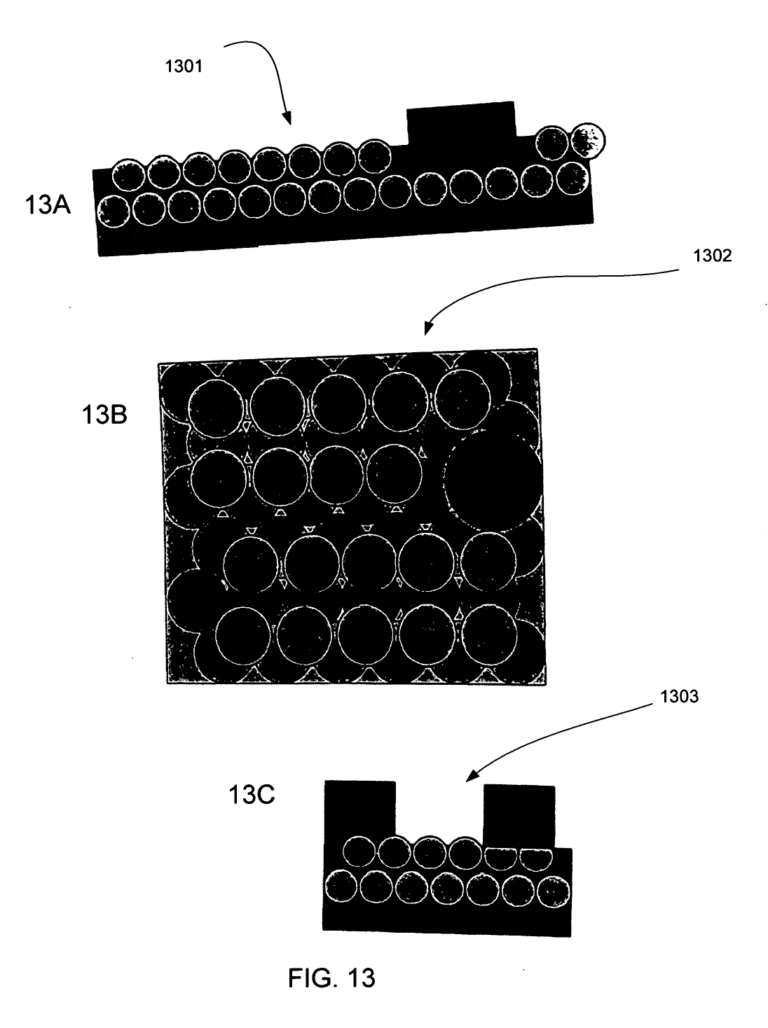

Referring now to FIG. 13, at 13A an SiO2 deposit with etches back is performed 1301 to gold endpoint with SOG possibly. At 13B a top view 1302 of some embodiments of the present invention is shown with exemplary orientation and at 13C a side view with image cutouts is shown 1303.

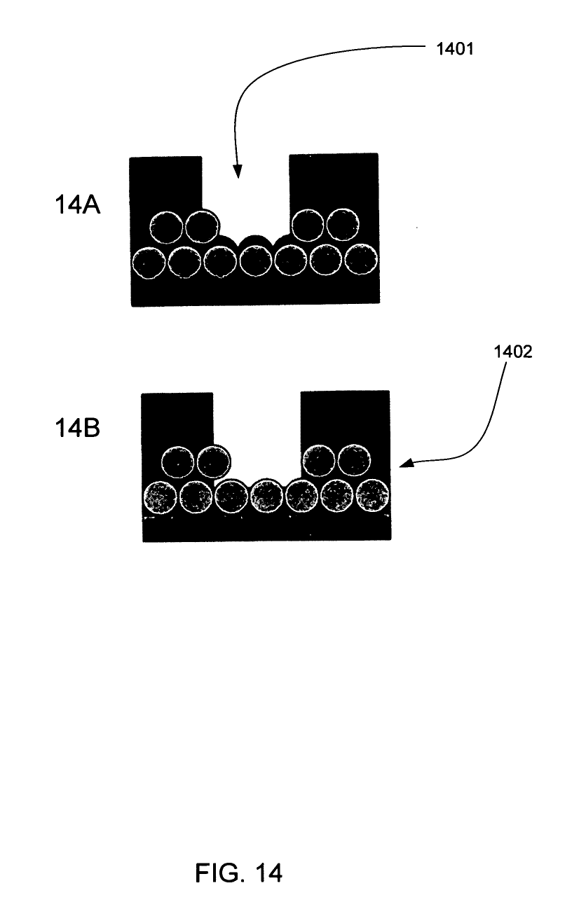

Referring now to FIG. 14, at 14A, a HF etch or dry etch 1401 can be performed. In some exemplary embodiments, the etch can include sphere removal. At 14B, a TiN or ALD barrier 1402 strip can be performed. In some embodiments, the strip can target ½ the distance between previous openings and can be inert to AU.

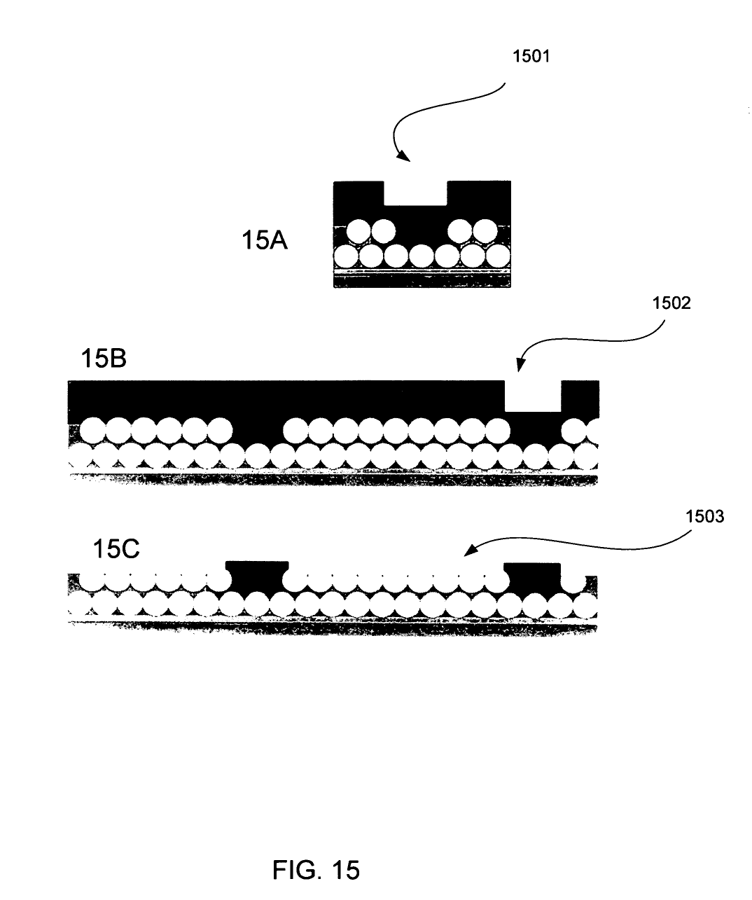

Referring now to FIG. 15, at 15A-15C a light SOG 1501 can follow vacuum drying 1502 with inert backfill 1503.

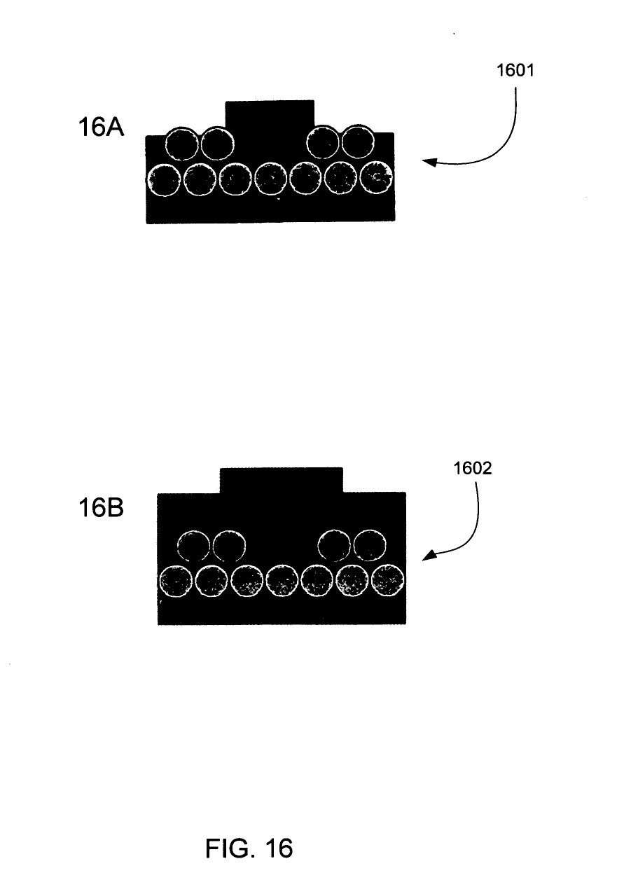

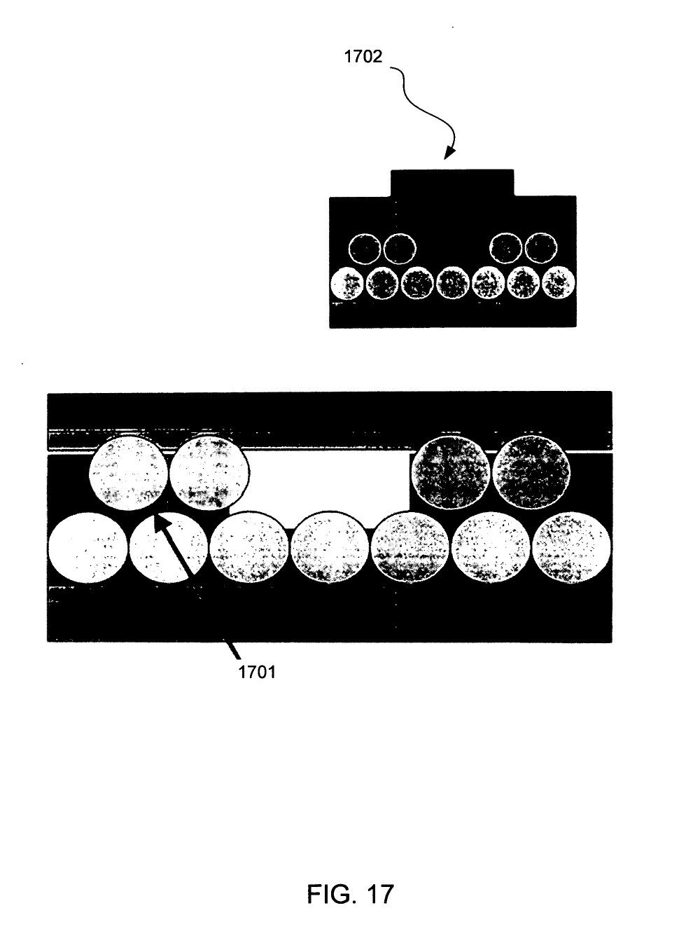

Referring now to FIG. 16, at 16A a strip resist step 1601 can be followed at 16B with a top contact EVAP 1602. Referring now to FIG. 17, a sinter/anneal solder step 1701 can be followed by a tunneling gap. The ambient may be SOG chemical or near vacuum if TEOS is used for black film. The dimension can be set by ALD film as opposed to other processing steps 1702.

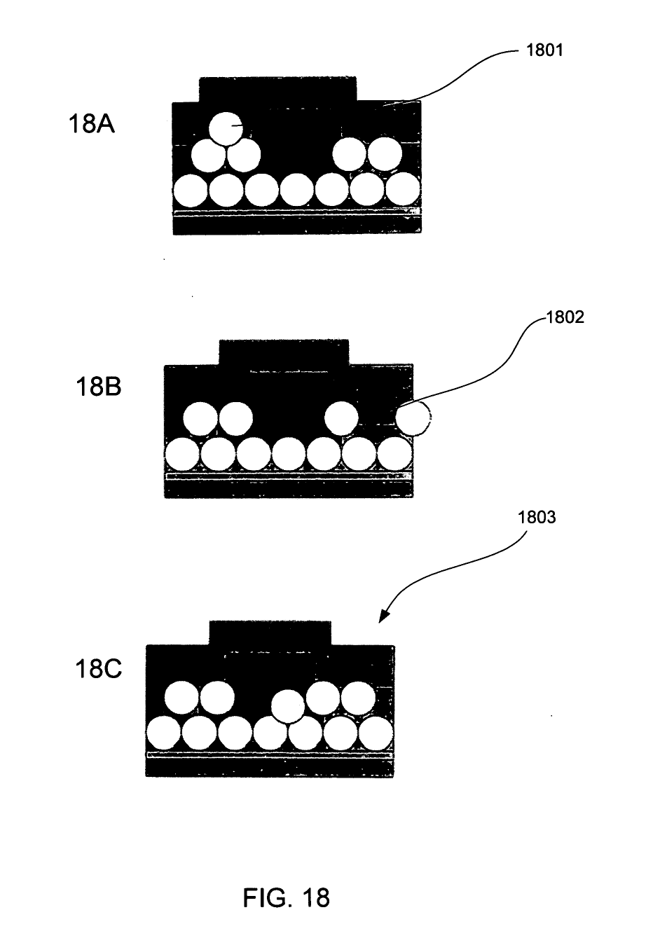

Referring now to FIG. 18, various anomalies that may be encountered while practicing the current invention are illustrated and include, at 18A an extra atom 1801 is illustrated. The extra atom 1801 may actually enhance a resulting thermoelectric device. There is not a detrimental effect to having extra metal in the top layer and the insulator plugs now includes a harder material to protect the tunnel area. At 18B a missing atom 1802 is not as much anticipated while practicing the present invention or in a device according to the present invention. At 18C, an atom in the etch area may require additional etching considerations 1803.

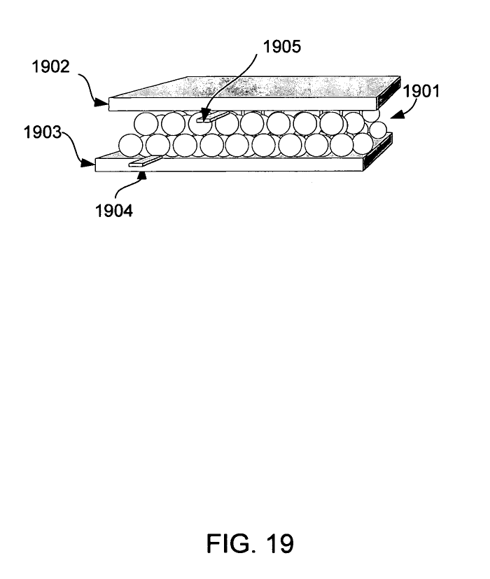

Referring now to FIG. 19, a thermoelectric device according to some embodiments of the present invention is illustrated. The P-type and N-type materials formed with the gold spheres and various layers 1901 described herein are contained within a first surface 1902 and second surface 1903. A positive terminal 1904 and a negative terminal 1905 are extended out from the N-type and P-type materials.

Systems

In general, the methods of the present invention may be implemented with industrial deposition machinery, such as spin coating machinery, suitable for applying layers of material on a conductor surface. In addition, the present invention includes an automated processor programmed cause machinery to execute the methods described herein.

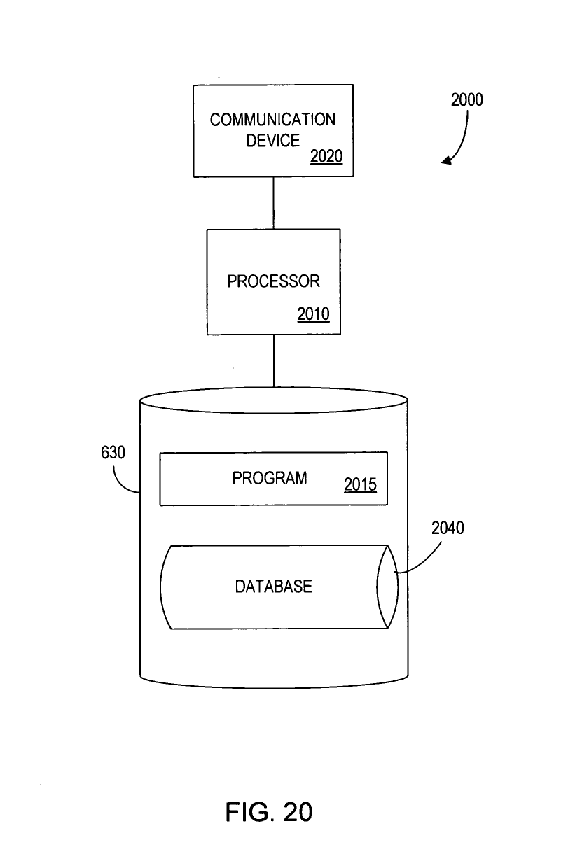

FIG. 20 illustrates a controller 2000 that can be used to control equipment and implement various embodiments of the present invention, as described herein. The controller 2000 comprises one or more processors 2010 coupled to a communication device 2020 configured to communicate via a communications buss or a communication network (not shown in FIG. 20) with one or more of various components of a computer system or automated equipment. The communication device 2020 may be used to communicate, for example, with one or more items of fabrication equipment used to implement the steps described above.

The processor 2010 is also in communication with a storage device 2030. The storage device 2030 may comprise any suitable information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 2030 can store a program 2015 for controlling the processor 2010. The processor 2010 performs instructions according to the stored program code 2015, and thereby operates in accordance with the present invention. For example, the processor 2010 may receive instructions from the stored program code instructing the processor to control one or more of: spin casting equipment, deposition equipment and etching equipment. The processor 610 may also transmit information comprising conditions under which the steps described herein are implemented.

The storage device 630 can store thermoelectric device manufacturing related data in a database 2040, and other data as needed. The illustration and accompanying description of the control processor presented herein is exemplary, and any number of other data processing or controller arrangements can be employed besides those suggested by the figures.

Conclusion

A number of embodiments of the present invention have been described. Nevertheless, it will be understood that various modifications may be made without departing from the spirit and scope of the invention. For example, various methods or equipment may be used to implement the steps described herein. In addition, various casings and packaging can also be included in order to better adapt a thermoelectric device according to the present invention to a specific application. Accordingly, other embodiments are within the scope of the following claims.

What is claimed is:

1. A method for forming a thermoelectric device, the method comprising:
coating a conductor with metallurgy comprising one or more of: Au and Sn material;
spin casting a first gold sphere monolayer onto the one or more of: Au and Sn material;
soaking a nanomaterial insulator material over the first gold sphere monolayer;
etching back the nanomaterial insulator material to a depth exposing at least a portion of the first gold sphere monolayer;
etching back the first gold monolayer until endpoints are formed comprising the first gold sphere monolayer;
spin casting a second gold monolayer on top of the nanomaterial insulator;
applying an attaching layer of material to facilitate adhesion of the second gold monolayer and the first gold monolayer;
depositing a metal film over the attaching layer; and
applying a mask on top of the metal film.

2. The method of claim 1, additionally comprising the step of stripping the metal film.

3. The method of claim 2, additionally comprising the step of applying a spin on glass layer.

4. The method of claim 3, additionally comprising the step of stripping the spin on glass layer.

5. The method of claim 4, additionally comprising the step of performing an EVAP process.

6. The method of claim 1 wherein the etching back of the nanomaterial insulator material is performed with an etching process comprising a wet etch.

7. The method of claim 1 wherein the etching back of the nanomaterial insulator material is performed with an etching process comprising a dry etch.

8. The method of claim 1 wherein the metal film comprises titanium.

9. A method of forming a thermoelectric device, the method comprising the steps of:
coating a conductive plate with a solder comprising one or more of: Au and Sn;
depositing a gold sphere monolayer onto the solder coating, wherein the depositing of the gold sphere monolayer comprises interstitial spaces between the gold spheres; and
applying a layer of insulating low conductivity material onto the gold spheres and filling multiple interstitial spaces;

10. The method of claim 9 additionally comprising the step of applying a layer of ALD insulator to the layer of insulating low conductivity material.

11. The method of claim 9 additionally comprising the step of applying a layer of TiN film of between 30 Ang and 60 Ang thick to the layer of insulating low conductivity material.

12. The method of claim 9 wherein the gold sphere monolayer is applied in dimensions at the macroscopic level.

13. The method of claim 9 additionally comprising the step of applying a second monolayer of gold.

14. The method of claim 9 wherein the second monolayer of spincast gold is applied via a spin coating process.

15. The method of claim 9 additionally comprising the steps of depositing a layer of SiO₂ and etching the SiO₂ to expose gold endpoints comprising the gold spheres.

16. A thermoelectric device comprising:
a conductor base;
a coating of metallurgy comprising one or more of: Au and Sn material coating said conductor;
a first gold sphere monolayer on top of the metallurgy comprising one or more of:
Au and Sn material;
a nanomaterial insulator material over the first gold sphere monolayer;
endpoints comprising the first gold sphere monolayer; and
a second gold monolayer on top of the nanomaterial insulator;

17. The thermoelectric device of claim 16 additionally comprising:
an attaching layer of material to facilitate adhesion of the second gold monolayer and the first gold monolayer; and
a metal film over the attaching layer.

18. The thermoelectric device of claim 16 additionally comprising a layer of spin on glass on top of the metal film.

19. The thermoelectric device of claim 18 wherein the conductor base comprises a copper plate.

20. The thermoelectric device of claim 16 wherein the first gold layer and the second gold layer comprise in dimensions at the macroscopic level
